(19) United States
(12) Patent Application Publication
(10) Pub. No.: US 2026/0149239 A1
(43) Pub. Date: May 28, 2026

(54) CIRCULAR BEAM TELECOMMUNICATIONS WAVELENGTH EDGE-EMITTING SEMICONDUCTOR LASER

(71) Applicant: University of Notre Dame du Lac, South Bend, IN (US)

(72) Inventors: Douglas C. Hall, South Bend, IN (US); Jideofor Ambrose Henry Odoeze, South Bend, IN (US)

(21) Appl. No.: 19/398,730

(22) Filed: Nov. 24, 2025

Related U.S. Application Data
(60) Provisional application No. 63/724,548, filed on Nov. 25, 2024.

(51) Int. Cl. H01S 5/22; C23C 14/18; C23C 16/02; C23C 16/40; C23C 28/00; H01S 5/34

(52) U.S. Cl. CPC H01S 5/22; C23C 14/18; C23C 16/0227; C23C 16/0236; C23C 16/402; C23C 28/322; C23C 28/345; H01S 5/3409

(57) ABSTRACT

The disclosed high-index-contrast single spatial mode edge-emitter semiconductor diode laser includes a substrate a ridge structure on the substrate that has an optical guiding region containing a quantum well active region sandwiched between cladding layers. An oxide may surround the ridge structure. A thickness of the optical guiding region may be less than a thickness of the cladding layers such that an empty space around the optical guiding region is maintained. Various other methods, systems, and devices are also disclosed.

### CROSS REFERENCE TO RELATED APPLICATION

This application claims the benefit of U.S. Provisional Application No. 63/724,548, filed Nov. 25, 2024, the disclosure of which is incorporated, in its entirety, by this reference.

### STATEMENT REGARDING FEDERALLY SPONSORED RESEARCH OR DEVELOPMENT

This invention was made with government support under grant 2329845 awarded by the National Science Foundation (NSF). The government has certain rights in the invention.

### BACKGROUND

Ever increasing data demands have increased burdens on data centers. For example, the exponential growth of Internet Protocol (IP) traffic due to the development and advancements in artificial intelligence (AI), cloud computing, and the growing connectivity of the Internet of Things (IoT) have driven up the cost of running data centers. Improved high-performance lasers with advanced integration ability are required to meet the rapidly increasing bandwidth.

Edge-emitting lasers have conventionally produced highly elliptical beams resulting in high astigmatism (e.g., inability to focus to a tight small spot) and thus reduced coupling efficiency to waveguides and fibers. Correcting this astigmatism, for example through the use of anamorphic prism or cylindrical lens pairs, often lead to increased cost and complexity and are not practical for monolithic photonic integration because these beam shaping optics are commonly added off-chip. Monolithic integration of stacked active and passive waveguides to incorporate tapered mode transformers may circularize an edge-emitting laser beam, but requires additional fabrication complexity that is often not feasible or economical.

Thus, there is a need for circular beam edge-emitting semiconductor lasers that may be fabricated without complexity.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIGS. 1A-1B illustrate an example edge-emitting semiconductor laser capable of a circular beam.

FIGS. 2A-2F illustrate example stages of fabricating an edge-emitting semiconductor laser capable of a circular beam.

FIG. 3 is a flow diagram of an exemplary method for fabricating an edge-emitting semiconductor laser capable of a circular beam.

FIG. 4 is a table of example material selectivity of various wet etch chemistries for III-V semiconductors.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to a high-index-contrast (HIC) single spatial mode edge-emitter semiconductor diode laser and fabrication methods thereof. In some examples, a InP-based 1550 nm HIC ridge waveguide (RWG) process may exhibit deep dry etching damage and sidewall roughness, which may be remediated through a slow, well-controlled selective lateral wet etch into the waveguide core region (as opposed to wet oxidation). The resulting structure may advantageously yield strong optical confinement to enable single-spatial mode waveguides without the cost and complexity of conventional epitaxial regrowth processing. Furthermore, fine tuning of the confinement width may achieve a dimension yielding a circularly symmetric optical mode with corresponding circularly symmetric beam divergence. Such improved beam quality may be desirable at the eye safe 1550 nm wavelength for free-space applications desiring a more circular illumination source for laser distance ranging, targeting, and surveying. For focused-spot applications and data telecommunications, the round and non-astigmatic laser beam may naturally enhance focused beam intensity and fiber coupling efficiency without the need for external circularizing optics. For datacom use, the structure provided herein may support improved direct modulation bandwidths given the inherently lower RC time constant achieved through preservation of a lower resistance (R) wide top contact width paired with reduced capacitance (C) as high dielectric constant semiconductor material is replaced with air in the waveguide plane.

Features from any of the implementations described herein can be used in combination with one another in accordance with the general principles described herein. These and other implementations, features, and advantages will be more fully understood upon reading the following detailed description in conjunction with the accompanying drawings and claims.

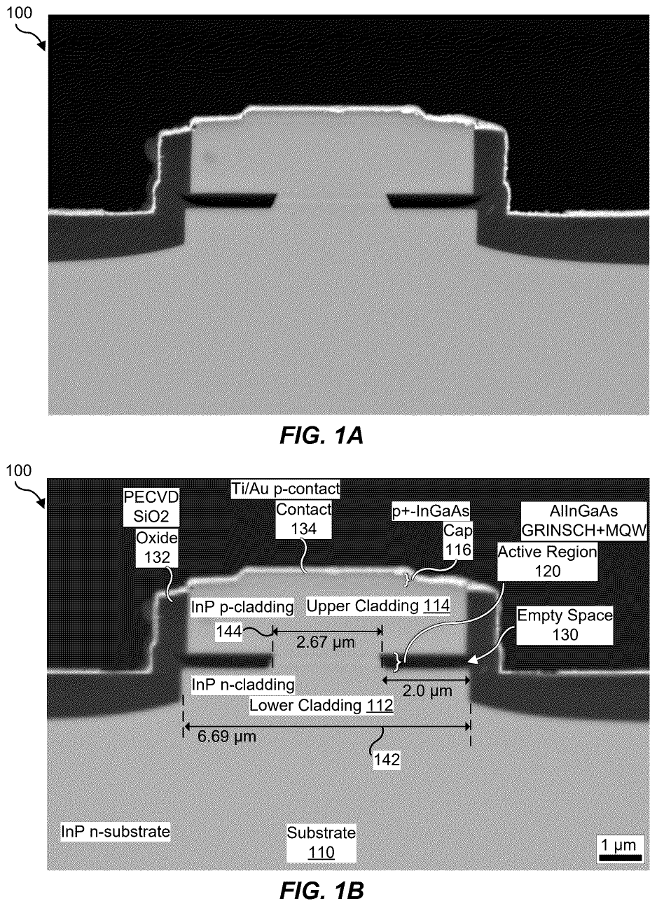

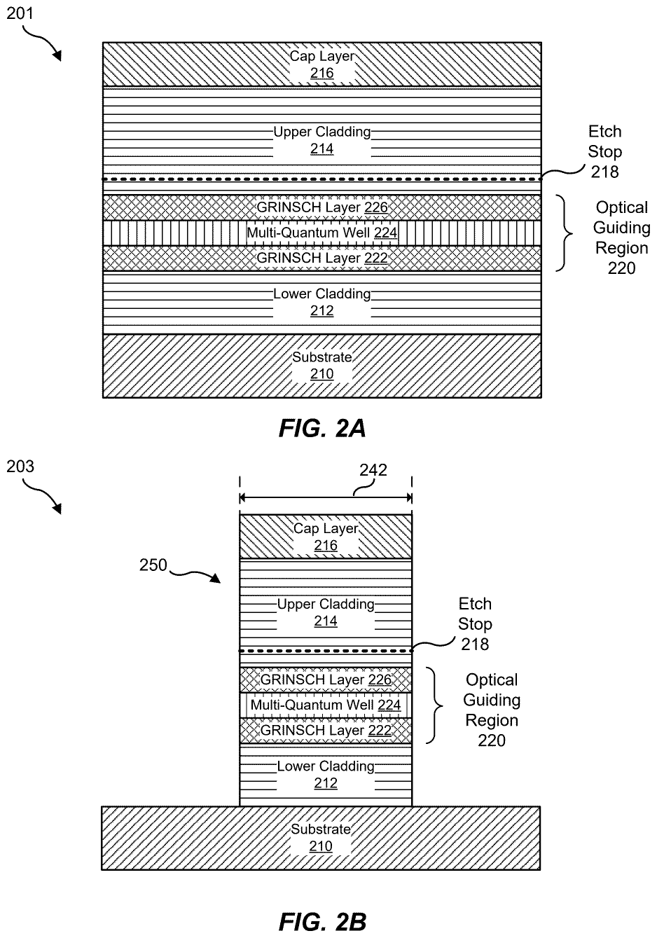

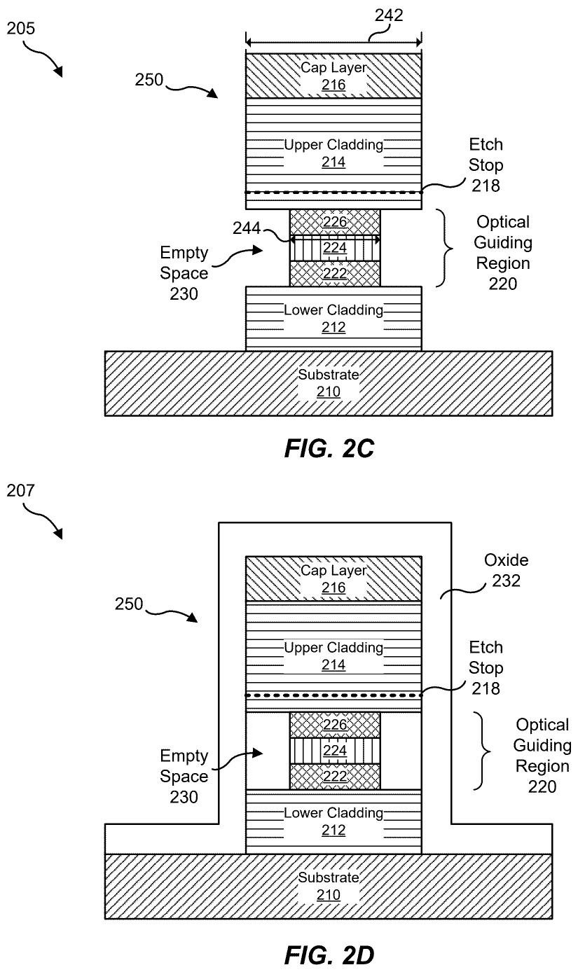

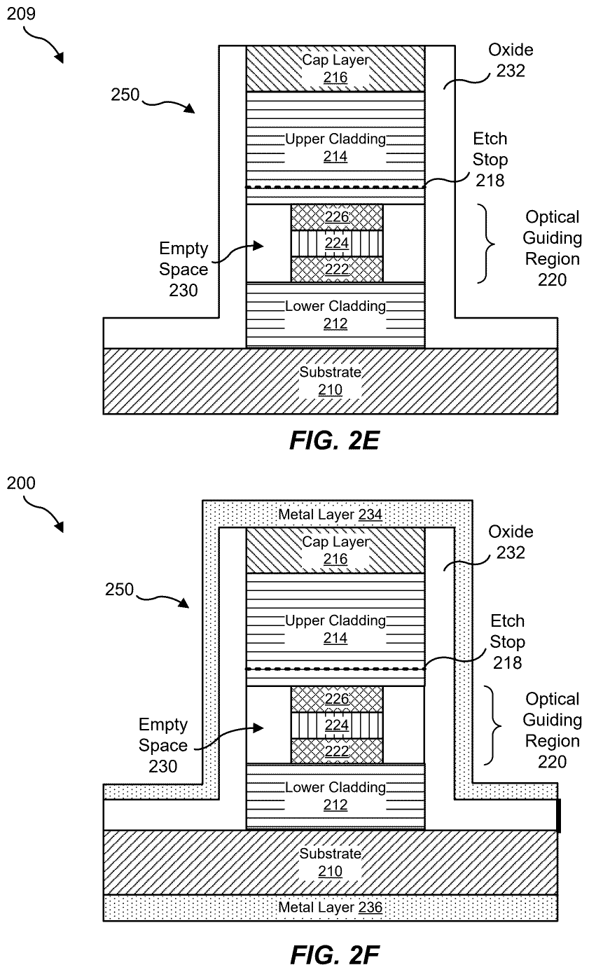

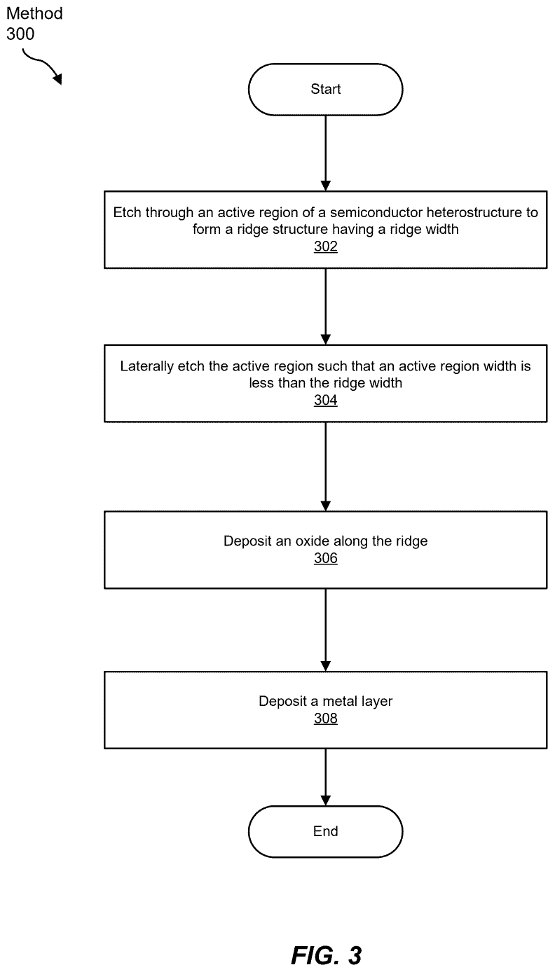

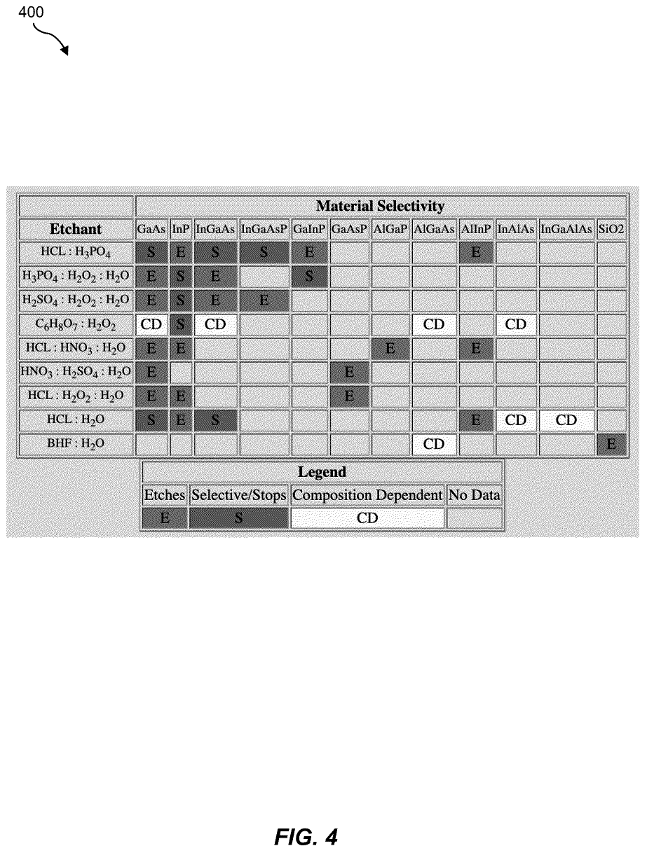

The following will provide, with reference to FIGS. 1-4, detailed descriptions of edge-emitting laser devices configured for circular beam. Detailed descriptions of an example device will be provided in connection with FIGS. 1A-1B. Detailed descriptions of example fabrication stages will be provided in connection with FIG. 2. Detailed descriptions of corresponding fabrication methods will also be provided in connection with FIG. 3. In addition, a table of example selective etchant is provided in FIG. 4.

A deep-etched ridge (e.g., a deep-ridge) laser is a type of laser device structure having ridges that are fabricated by etching through the cap, cladding, optical guiding region (OGR), and into the lower n-clad. Dielectric is then deposited and a window is opened for metallization. This laser structure provides strong lateral confinement of both current (carriers) and photons and, importantly, enables the fabrication of integrated devices with small radius bends having low bend loss due to their high index contrast. However, such devices are can suffer from high sidewall optical scattering losses and sidewall surface-related non-radiative recombination issues that may affect laser reliability and stability over time, which has been a major challenge to their development.

Turning to FIGS. 1A-1B, FIGS. 1A and 1B (an annotated version of FIG. 1A) illustrate a device 100, including a substrate 110 (e.g., InP n-substrate or other suitable material), a lower cladding 112 (e.g., InP n-cladding or other suitable material), a ridge width 142, an active region 120 (e.g., a multi-quantum well heterostructure as will be described further below, and which in some examples may also refer to corresponding waveguide structures), an active region width 144, an empty space 130, an upper cladding 114 (e.g., InP p-cladding or other suitable material), a cap 116 (e.g., p+-InGaAs or other suitable material), an oxide 132 (e.g., SiO₂ or other suitable material as may be deposited via PECVD), and a contact 134 (e.g., a Ti/Au p-contact or other suitable material). As illustrated in FIG. 1, a ridge structure (e.g., comprising lower cladding 112, active region 120, upper cladding 114) may be disposed on substrate 110, and isolated via oxide 132 along its sidewalls, with a metal layer (e.g., contact 134) thereover. In the example illustrated in FIG. 1, the ridge structure has ridge width 142 of approximately 6.69 μm, which is greater than active region width 144 of approximately 2.67 μm. This may establish empty space 130 of approximately 2.0 μm around active region 120. Notably, empty space 130 may be a gap free of any solid material (e.g., free of oxide 132) such that air may be trapped therein.

More specifically, FIG. 1A illustrates a SEM cross sectional image of a wₐ=2.67 μm active core width (e.g., active region width 144) high index contrast (HIC) ridge waveguide (RWG) laser that may be formed by a 20 minute selective citric peroxide wet etch of a 6.75 μm dry-etched ridge.

Although the InGaAsP quaternary alloy is commonly used for telecom applications, AlInGaAs may be used due to its larger conduction band offsets which provide better electron confinement for improved thermal stability and enhanced differential gain. The 1550 nm AlInGaAs/InP multi-quantum well (MQW) laser heterostructure in the examples described herein (e.g., active region 120) may be grown via metal organic chemical vapor deposition (MOCVD) and may, in some implementations, comprise five compressively strained 6 nm Al_{0.07}Ga_{0.22}In_{0.71}As quantum wells with photoluminescence peak around 1530 nm, separated by tensile strained 10 nm Al_{0.22}Ga_{0.29}In_{0.49}As barrier layers. This active region is symmetrically sandwiched by two 120 nm Al_{0.34→0.42}Ga_{0.13→0.05}In_{0.53}As graded-index separate-confinement-heterostructure (GRINSCH) layers within the lower n-type InP (e.g., lower cladding 112) and upper p-type InP cladding (e.g., upper cladding 114) layers. The total thickness of the AlInGaAs GRINSCH+MQW active region layers is 330 nm. The contact layer (e.g., contact 134) is 200 nm of highly-doped p⁺(>1.5×10¹⁹ cm⁻³) In_{0.53}Ga_{0.47}As.

Spatial lateral mode confinement is achieved through a deep etch of the ridge (e.g., through the active region into the n-type cladding), followed by the use of a lateral selective wet etch of the AlInGaAs GRINSCH+MQW active region to further reduce the active core mode confinement width, wₐ. Scattering loss associated with deep-etched sidewall interface roughness can severely inhibit waveguide shrinking, as the scattering loss grows proportional to 1/(wₐ)⁴. This makes it challenging to realize high-index-contrast ridge waveguide (HIC RWG) lasers with dimensions supporting only a single spatial mode, let alone the further width reduction required to achieve a circularly symmetric mode. Dry-etched sidewalls also experience plasma ion damage which creates non-radiative recombination centers near the surface. As will be described further below, the methods provided herein follow the deep dry etch with a ˜2.0 μm lateral selective wet etch of the AlInGaAs optical guiding layer to both remove ion damaged material and smooth the sidewall surface roughness.

FIGS. 2A-2F illustrate various schematic stages of fabricating a device such as device 100. FIG. 2A illustrates a stage 201. FIG. 2A illustrates an initial or precursor state of a heterostructure that includes layers for a substrate 210 (corresponding to substrate 110), a lower cladding 212 (corresponding to lower cladding 112), an upper cladding 214 (corresponding to upper cladding 114), and a cap layer 216 (corresponding to cap 116). FIG. 2A also includes an optical guiding region 220 (corresponding to active region 120), collectively formed from a GRINSCH layer 222, a multi-quantum well 224, and a GRINSCH layer 226.

As described herein substrate 210 may be made of any suitable substrate material, such as an InP n-substrate. The cladding layers may also be made of any suitable material, such as InP. More specifically, in some implementations, lower cladding 212 may be an InP n-cladding and upper cladding 214 may be an InP p-cladding. Optical guiding region 220 may also be made of any suitable material, such as AlInGaAs. More specifically, in some implementations, GRINSCH layer 222 and/or GRINSCH layer 226 may be AlInGaAs GRINSCH layer, and multi-quantum well 224 may be an AlInGaAs MQW. Further multi-quantum well 224 is sandwiched between GRINSCH layer 222 and GRINSCH layer 226, as well as optical guiding region 220 sandwiched between lower cladding 212 and upper cladding 214. Cap layer 216 may be made of any suitable material, such as InGaAs. More specifically, cap layer 216 may be p⁺-InGaAs.

Quantum well heterostructures may provide in-plane, edge-emitting laser via separate confinement heterostructures (SCH), in which carriers and photons may be transversely (e.g., perpendicular to the layers, such as in the crystal growth direction) confined in the quantum well and optical guiding region (e.g., waveguide and active region), respectively. For SCH structures, an active region (e.g., MQW) is sandwiched by a waveguide region, which in turn is sandwiched by a cladding region, which is finally sandwiched by an electrical connection region.

The electrical connection region may include a p-type top cap layer (e.g., cap layer 216) from which holes are injected, and a n-type substrate lower layer (e.g., substrate 210) from which electrons are injected. The p-type cap layer may be highly doped to reduce p-contact resistance.

The cladding region may include p-type (e.g., upper cladding 214) and n-type (e.g., lower cladding 212) cladding layers, which may be doped to provide conductivity of current (e.g., flow of carriers) to the waveguide region. The cladding region may be doped at reduced levels closer to the waveguide core to reduce free-carrier absorption of the guided external field (e.g., mode evanescent wave within the cladding).

The waveguide region (e.g., GRINSCH layer 222 and GRINSCH layer 226) may be an unintentionally doped (UID) region where generated photons may be confined via total internal reflection (TIR). Carriers may move through the waveguide region into the active region via carrier concentration gradients.

The active region (e.g., multi-quantum well 224) may include quantum wells and barriers and is often undoped. This active region allows recombination of carriers, providing gain through the stimulated emission of photons. An optical guiding region (OGR) (e.g., optical guiding region 220) includes the waveguide region (e.g., GRINSCH layer 222 and GRINSCH layer 226) and the active region (e.g., multi-quantum well 224), and may also provide a transverse waveguide core layer.

The heterostructure illustrated in FIG. 2A may be formed by any appropriate process. For example, the various layers of materials may be deposited (e.g., grown via metal-organic vapor phase epitaxy), doped/implanted, etc., with additional supporting steps therebetween. FIG. 2A represents a graded index separate confinement heterostructure (GRINSCH).

FIG. 2A further illustrates an etch stop 218, which may be optional. In conventional ridge laser structures and related fabrication processes, etch stop 218 may be used when forming a ridge structure so as to avoid etching into the layers for optical guiding region 220. However, as will be described further below, the systems and methods provided herein may etch deeper than the conventional etch stop. Although the heterostructure in FIG. 2A may be formed without etch stop 218, in some examples, a conventionally available heterostructure may include etch stop 218. In other words, conventional ridge structures are formed by etching the cap layer and upper cladding layers, with etch stop 218 used to prevent etching deeper than the upper cladding layer. Details on conventional RWGs are further provided in Odoeze, J. A. H. (2025), Performance and Reliability of Deep-Etched High-Index-Contrast Ridge Waveguide Lasers (Version 1), University of Notre Dame, available at https://doi.org/10.7274/29505104.v1, the disclosure of which is incorporated by this reference.

Continuing to FIG. 2B, FIG. 2B illustrates a stage 203 of performing a deep etch (e.g., a deep dry etch). As illustrated in FIG. 2B, a ridge structure 250 (e.g., including lower cladding 212, optical guiding region 220, upper cladding 214 and cap layer 216) is formed on substrate 210 having a ridge width 242 (corresponding to ridge width 142) by etching into lower cladding 212, which may include etching to substrate 210.

In one example, a plasma-enhanced chemical vapor deposition (PECVD) SiNₓ layer is first deposited on a 1 cm×1 cm cleaved and cleaned sample to serve as a mask, such as a dry etch mask (in relation to FIGS. 2A and 2B), and later as a wet etch mask (as will be described further below with respect to FIG. 2C). Ridge width 242 may be defined as desired using an appropriate lithography system. Deep etching may be performed in an inductively coupled plasma reactive ion etching (ICP-RIE) system using, for instance, Cl₂, CH₄, and H₂ gases.

As illustrated in FIG. 2B, by etching into the cap, cladding, OGR and into the lower cladding layers, the resulting ridge structure 250 (e.g., a deep-etched ridge or deep ridge) may provide strong lateral confinement of both current (carriers) and photons, and allows fabrication of integrated devices with small radius bends having low bend loss due to the high index contrast. However, deep ridge structures often suffer from sidewall surface related recombination issues that may affect laser reliability and/or stability over time. Although oxidizing (e.g., the sidewalls), may alleviate some of these issues, other issues (e.g., thermal degradation in the form of dissociation and pitting during InP oxidation) may arise. The present disclosure further describes an alternative that may avoid these issues while addressing the previously described issues of deep ridge structures.

FIG. 2C illustrates a stage 205 of a selective lateral etch (e.g., a deep lateral wet etch). The etch may be selective in that optical guiding region 220 may be laterally etched (e.g., etched into from the sidewalls, generally perpendicular to crystal growth direction) whereas other materials/layers (e.g., cap layer 216, upper cladding 214, lower cladding 212 and/or substrate 210) may not be substantially etched, forming an empty space 230 (e.g., surrounding/around sidewalls of optical guiding region 220). The lateral etch may be deep such that an active region width 244 (corresponding to active region width 144) may be less than ridge width 242. In some examples, the difference in widths may be significant, for instance active region width 244 being approximately 30-40% of ridge width 242 such that approximately 20-30% of ridge width 242 was laterally etched through each sidewall, and/or the lateral etch depth being similar to (e.g., approximately 75% of) the resulting active region width 244, although in other examples, other lateral etch depths may be used (resulting in desired relative widths). In other words, empty space 230 may have dimensions based on a thickness of optical guiding region 220 and width differential between ridge width 242 and active region width 244 (e.g., each empty space 230 having half of the width difference), as illustrated.

In one example, the lateral etch may be performed, using a mixture of 55 mL of citric acid solution (1 g C₆H₈O₇:1 mL deionized H₂O) and 5.5 mL of 30% H₂O₂, for a controlled and selective wet etch with an etch rate of 102.2±1.1 nm/min, 6.7±0.5 nm/min, and 1.9±0.4 nm/min for the AlInGaAs active core, p-InP, and n-InP, respectively. The wet etch mask may be the same as the dry etch mask (e.g., SiNₓ etch mask as previously discussed).

The interface of the wet etched active region core may have a measured slant angle of 67.8°, attributed to the upper p-type AlInGaAs GRINSCH waveguide layers etching faster than the lower n-type layers (and noting that a (111) plane would be 54.74° to the (110) etched sidewall plane).

Turning now to FIG. 2D, FIG. 2D illustrates a stage 207 for device isolation. An oxide 232 of any suitable insulating/dielectric material may be formed around ridge structure 250, covering, for example, a top surface of cap layer 216 and substrate 210, as well as sidewalls of cap layer 216, upper cladding 214, and lower cladding 212. In some examples, oxide 232 may not substantially enter into empty space 230, generally maintaining dimensions of empty space 230 as illustrated in FIGS. 2C-2D, although in other examples oxide 232 may intrude into empty space 230 (e.g., from outside and towards optical guiding region 220 and/or along inner walls such as under upper cladding 214, on lower cladding 212, and/or along sidewalls of optical guiding region 220).

In one example, the SiNₓ etch mask (e.g., dry/wet etch mask) may be removed in a CHF₃/O₂ plasma and a PECVD SiO₂ insulation layer is deposited. While PECVD is typically conformal, the inside of the wet-etched core may not be coated as a result of its high aspect ratio.

FIG. 2E illustrates a stage 209 of a window opening. For instance, a photolithography exposure may open a contact window atop ridge structure 250.

Continuing to FIG. 2F, FIG. 2F illustrates a stage 200 corresponding to device 100, generally representing a finalized/nearly finalized device. A metal layer 234 may be formed over/around ridge structure 250 (e.g., on the exposed top surface of cap layer 216 and along/over oxide 232) as well as on substrate 210 (e.g., on the exposed surface of substrate 210 opposite ridge structure 250 or cap layer 216). Metal layer 234 and metal layer 236 may be made of any suitable conductive material, and may be the same or different material.

In one example, after the photolithography exposure to open the contact window atop ridge structure 250, Ti/Au (e.g., metal layer 234) and AuGe/Ni/Au (e.g., metal layer 236) metallizations are deposited to the p+-InGaAs cap layer and the n-InP substrate, respectively. Next, the fabricated chip may be cleaved into bars of lengths typically between 350-1000 microns, passivation coatings may be applied to the laser facets to suppress facet degradation and prevent catastrophic optical mirror damage (COMD) failure at high output powers, and bars may be singulated into individual laser devices for probe testing and final packaging including solder bonding to heatsinks.

The dimensions/values described herein provide non-limiting examples. However, in reference to FIG. 1B, for wₐ>2.67 μm, the lasers may exhibit the traditional elliptical beam shape, with increasing ellipticity, conventional for most edge-emitting lasers. However, for both wₐ=2.42 μm and 2.67 μm, the lasers may exhibit a near-perfect circular output beam with closely matched 1/e² beam widths for both X and Y axes. Of particular note, when shrinking wₐ even further, the lasers may exhibit “inversion” of the typical edge-emitter output beam elliptical symmetry, where the lateral X dimension near field width actually becomes smaller than the Y dimension near field width, such that the traditional “fast” (vertical, perpendicular, or out of plane) beam divergence axis is now slower than the traditional “slow” (lateral, parallel, or in plane) beam divergence. To reach this limit of width shrinkage and still achieve lasing highlights the efficacy of the ˜2.0 μm lateral wet etch for significantly minimizing both the dry etch damage and interface roughness in this HIC RWG laser structure.

In comparing a 2.67 μm core width circular-mode HIC wet-etched device (e.g., FIGS. 1B) and 3 μm conventional weakly index guided (etch stop) ridge lasers, the HIC devices may have an improved internal differential quantum efficiency of 68% vs. the 58% for the conventional weakly index guided devices as current, carriers and photons are altogether better confined, resulting in higher carrier injection efficiency above threshold. Unexpectedly, the HIC devices may also exhibit a slightly lower distributed scattering loss of 17.4 cm⁻¹ vs the 18.3 cm⁻¹ for the conventional device, for instance due to the deep anisotropic lateral wet-etch having more effectively smoothed the etched sidewall roughness. A notable trade-off is a 2.6× increase in the threshold current density (2833 A/cm² vs (1093 A/cm²) of the HIC vs. comparison conventional devices for similar length (˜1800 μm) lasers. Although InP-based laser material has been experimentally shown to be much less sensitive to surface states than GaAs-based heterostructures, the increase in threshold current density may be due to surface non-radiative recombination loss at the unpassivated wet etch exposed AlInGaAs surface. Therefore, in some examples, the addition of a passivation layer like a wet thermal native oxide or atomic layer deposition (ALD) dielectric following the wet etch may be performed (e.g., filling at least a portion of empty space 230 with oxide, not illustrated). However, the examples having empty space 230 as described herein may allow evanescent field sensing with gas or liquid material filling the empty space adjacent to the active laser waveguide core.

FIG. 3 is a flow diagram of an exemplary method 300 for fabricating an edge-emitting laser device as provided herein. The steps shown in FIG. 3 can be performed by any suitable fabrication processes and/or systems. In one example, each of the steps shown in FIG. 3 represent multiple sub-steps, examples of which will be provided in greater detail below.

As illustrated in FIG. 3, at step 302 one or more of the systems described herein etch through an active region of a semiconductor heterostructure to form a ridge structure having a ridge width. For example, as illustrated in FIGS. 2A-2B, the semiconductor heterostructure may be etched (e.g., through optical guiding region 220 and down to substrate 210) to form ridge structure 250. The systems described herein can perform step 302 in a variety of ways. In some examples, etching through the active region comprises a dry etch as described above.

At step 304 one or more of the systems described herein laterally etch the active region such that an active region width is less than the ridge width. For example, ridge structure 250 may be selectively laterally etched (e.g., etching optical guiding region 220) such that active region width 244 is less than ridge width 242 (see also active region width 144 and ridge width 142 in FIG. 1B). The systems described herein can perform step 304 in a variety of ways. In one example, laterally etching comprises a selective etch configured to etch the active region without substantially etching the ridge structure. In some examples, the selective etch comprises a wet etch. In some examples, laterally etching the active region smoothens sidewalls of the active region from the dry etch.

At step 306 one or more of the systems described herein depositing an oxide along the ridge structure. For example, oxide 232 may be formed on ridge structure 250 (see, also oxide 132 in FIG. 1B). The systems described herein can perform step 306 in a variety of ways. In one example, depositing the oxide along the ridge structure comprises depositing the oxide along sidewalls of the ridge structure without depositing the oxide along sidewalls of the active region. In some examples, depositing the oxide maintains an empty space around the active region.

At step 308 one or more of the systems described herein deposit a metal layer. For example, metal layer 234 is deposited over ridge structure 250 (see, also contact 134 in FIG. 1B) and metal layer 236 is deposited on substrate 210. The systems described herein can perform step 308 in a variety of ways. In one example, depositing the metal layer comprises depositing a first metal layer (e.g., metal layer 234) over the ridge structure (e.g., ridge structure 250) and depositing a second metal layer (e.g., metal layer 236) along a substrate (e.g., substrate 210) opposite the ridge structure. In some examples, step 308 includes removing the oxide from a top surface of the ridge structure before depositing the metal layer (e.g., window opening as in FIG. 2E). In some examples, additional processing steps may finalize the device.

As detailed above, a simple single spatial mode 1550 nm laser structure realized through combined deep dry etching plus lateral selective AlInGaAs core wet etching capable of achieving a circularly symmetric, non-astigmatic output beam for enhanced coupling efficiency to fibers without the need for beam shaping optics. With its reduced RC product also capable of supporting higher direct modulation rates, the structure described herein may advantageously provide multiple attractive and enabling performance capabilities desirable for addressing the cost and technology demands of today's growing data communications market.

FIG. 4 illustrates a table 400 of material selectivity of various example wet etch chemistries for certain (common) III-V semiconductors. The selective etches described herein may use any of the etchants in table 400 as needed based on the materials to be etched and/or not etched. In addition, the following description provides general non-limiting examples of example process flows, which may be combined with and/or replace the examples and steps described above.

### General Process Flow

1. Cleave Samples to 1 cm×1 cm size and then CO₂ snowjet.
2. Sample Solvent Clean.
Drytek 4 min
>5 min Acetone (ACE)
>5 min IsopropylAlcohol (IPA)
Rinse in running DI water
3. Refresh Etch
Depending on the top layer, to remove native oxide.
1:4 HCl:H₂O for 5 s will remove native oxide without etching the InGaAs (IQE InP material) or GaAs (AlGaAs-GaAs Material) cap layer.
1:4 HCl:H₂O for 5 s will remove native oxide without etching the InGaAs (IQE InP material) or GaAs (AlGaAs-GaAs Material) cap layer.
4. SiNₓ PECVD deposition (In house deposition)
SiH₄/NH₃: 40/4 sccm
Pressure: 500 mT
Power: 200 W
Rate: 14.2 nm/min.
Deposit for 60 min ≈850 nm in thickness.
5. Laser Ridge defining Lithography
Sample under vacuum in Hexamethyldisilazane (HMDS) for 120 s
Spin SPR 700-1.2 using JD400030 recipe (4000 rpm for 30 s with 2000 ramp).
Pre-exposure (soft) bake at 90° C. for 60 s
Expose AutoStepper using BLASERWIRE mask for 0.28 s
Develop in AZ917 for 45 s and then quick dip in DI
6. Exposure
Autostepper
0.28 s using BLASERWIRE mask
No hard bake
AZ917 MIF for 45 s
Heidelberg MLA 150
Dose of 67 mJ
Hard bake at 110° C. for 120 s
AZ917 MIF for 60 s
7. O2 Descum in PVA
recipe: ICFab Descum
Time: 30 s
Pressure: 300 mT
Power: 600 W
8. SiNₓ etch-patterned SiNₓ serve as etch and oxidation mask
RIE
Recipe: JD SiNₓ
CF₄/O₂: 25/2 sccm
RF: 75 W (DC bias ˜202 V)
Pressure: 30 mT.
Oxford ICP
Recipe: JD SiNₓ UCSB
CHF₃/O₂: 40/10 sccm
RF/ICP: 30 W/500 W (bias ˜V)
Pressure: 5 mT.
9. SPR Photoresist Removal
>8 min Acetone
>8 min IPA
DI rinse
4 min drytek
10. AlGaAs-GaAs Etch
RIE Etch (JD GAABk recipe)
BCl3: 10 sccm
Pressure: 10 mT
Power (RF): 50 W
Etch rate: ˜23.5 nm/min
Temperature: 20° C.
DC Bias ˜78 V
ICP Etch (J AlGaAs orig)
BCl₃/Cl₂: 12.5/2.5 sccm
Pressure: 5 mT
Power (RF1/RF2): 70 W/500 W
ER: TSiNₓ+NL ˜5.5 μm for 1.5 min
Temperature: 25° C.
DC Bias ˜100V
11. InP-Based Material Etch
Cl₂/CH₄/H₂: 10/18/12 sccm
Pressure: 3 mT
Power (RF1/RF2): 150 W/1000 W
ER: TSiNₓ+NL ˜3.6 μm for 2.5 min, and 4.6 μm for extra 1.5 min
Temperature: 20° C.
DC Bias ˜100V
12. Sample Solvent clean
same as in step 2
13. Oxidation (III-V furnace), an example of oxidation condition is;
Time: 66 min
Temperature: 420° C.
O₂/N₂ (H₂O): 2000 ppm
14. RIE SiNₓ-remove the SiNₓ etch and oxidation mask
same as in step 8
If self-alignment is achieved then you skip to step 15
15. Dielectric Deposition/Metal Contact Window Opening process
Otherwise sample solvent Clean without Oxygen plasma (Drytek or PVA)
15 min PECVD SiO₂ deposition
Sample under vacuum in Hexamethyldisilazane (HMDS) for 60 s
Spin 3-4 drops SPR 220-7 using JDstep recipe (4000 rpm for 30 s with 2000 rpm/s+5000 rpm for 5 s with 5000 rpm/s).
Pre-exposure bake for 120 s at 115° C.
Expose using Heidelberg MLA 150 with 400 mJ/cm² dose. This dose may depend on the height of the ridge which determines the thickness of the resist on the ridge.
≥35 min wait
Post-exposure bake for 120 s at 115° C.
60 s develop in Megaposit MFTM-24A developer
Descum as in step 6
Buffered-Oxide-Etch (BOE) and inspect
Resist removal as in step 9
16. Device Isolation Lithography/BiLayer Lift-Off process
Sample solvent clean, same as in step 2
Hexamethyldisilazane (HMDS) not required for LOR 3A
Spin LOR 3A using JD400030 recipe (4000 rpm for 30 s with 2000 ramp).
Bake for 300 s at 190° C.
Spin SPR 700-1.2 using JD400030 recipe (4000 rpm for 30 s with 2000 ramp).
Pew-exposure bake for 60 s at 90° C.
Expose using Heidelberg MLA 150 with 67 mJ/cm2 dose
Post-exposure bake for 120 s at 110° C.
Develop in AZ917 for 120 s and then quick dip in DI.
Descum
17. P-side Metallization (Oerlikon 450B SCSS)
Mount sample on 4″ wafer
100° A Ti
1000° A Au
18. Bilayer Lift-off Process Completion
Soak sample in PG remover at 110° C. for 30 min PG remover on a hot plate set to 110° C. over 30 min, results to 80° C. PG remover
19. Lapping and Polishing (Allied Multiprep System)
Mount Sample onto polishing platen
(a) Heat platen to ˜135° C.
(b) Apply clear wax to platen
(c) Gently place sample face down into wax
(d) place platen on mounting press and gently apply pressure
9 μm paper down to ˜125 μm thick
(a) 150 RPM, CCW, full load
3 μm slurry on white pad to complete mirror shine (˜110 μm thick)
(a) 200 RPM, CW, full load
(b) Continue until all scratches removed from sample backside
1 μm slurry on black pad until final thickness of ˜100 μm
(a) 200 RPM, CW, full load
20. Wax removed in acetone
(a) Soak in acetone until sample is free of wax, typically 6-8 hours
21. Refresh etch, same as in step 4
22. N-side Metallization (Oerlikon or FC1800 1 Evaporator)
Ti Gettering
˜360° A Au_{0.88}Ge_{0.12} @ 2° A/sec. 1 pellet in thermal boat
˜60° A Ni @ 1° A/sec. Final thickness ratio of 1:6 Ni:Au_{0.88}Ge_{0.12}
1000° A Au @ 2° A/sec.
23. Metal Anneal (Allwin RTP)
7 s @ 410° C. 400 s ramp up and down
24. Cleave laser bars
Align sample on heat release tape
Scribe sample using diamond scribe while tape is held by vacuum, and everything monitored under the microscope
25. Release sample on 90° C. hot plate.

### Indium Phosphide Based Laser Process Flow

1. Cleave Samples to 1 cm×1 cm size and then CO2 snowjet.
2. Sample Solvent Clean.
Rinse in running DI water
>5 min Acetone (ACE)
>5 min IsopropylAlcohol (IPA)
3. Refresh Etch
Depends on the top layer, to remove native oxide.
1:4 HCl:H₂O for 5 s (cap layer is InGaAs)
4. PECVD Dielectric Deposition
SiNₓ inhouse recipe
SiH₄/NH₃: 40/4 sccm
Pressure: 500 mT
Power: 200 W
Rate: 14.2 nm/min.
SiO₂ inhouse recipe
Temperature: 250° C.
5. Laser Ridge defining Lithography
Sample under vacuum in Hexamethyldisilazane (HMDS) for 60 s
Spin SPR 700-1.2 using JD400030 recipe (4000 rpm for 30 s with 2000 ramp).
Softbake for 60 s at 90° C.
Expose AutoStepper using BLASERWIRE mask for 0.28 s
Develop in AZ917 for 45 s and then quick dip in DI
6. O2 Descum (PVA)
Time: 30 s
Pressure=300 mT
Power=600 W
7. RIE SiNₓ etch-patterned SiNₓ serve as etch and oxidation mask
Recipe: JD SiNₓ
CF₄/O₂: 25/2 sccm
RF: 75 W (typical DC bias ˜202 V)
Pressure: 30 mT.
8. SPR Photoresist Removal
>8 min Acetone
>8 min IPA
DI rinse
4 min drytek
9. Ridge Etch
ICP Etch (recipe: JD InPBk)
Cl₂/CH₄/H₂: 10/18/12 sccm
Pressure: 3 mT
Power (RF1/RF2): 150 W/1000 W
Temperature: 20° C.
Etch rate: ˜1.86 μm/min for InP, and ˜151 nm/min for SiNₓ
10. InP sample Wet Etch (using Fig. B.1 as guide)
HCl:H2O 1:1 for 10 s (Etches AlInGaAs and InP but not InGaAs)
11. Oxidation (III-V furnace), example of an oxidation given
Time: 66 min
Temperature: 500° C.
O2/N2 (H2O): 7000 ppm
12. RIE SiNₓ-remove the SiNₓ etch and oxidation mask
same as in step 7
If self alignment is achieved then you skip to step 14
13. Dielectric Deposition/Metal Contact Window Opening process
Sample solvent clean, same as in step 2/item RIE SiNx deposition same as in step 4
Sample under vacuum in Hexamethyldisilazane (HMDS) for 60 s
Spin 3-4 drops SPR 220-7 using JD400030 recipe (4000 rpm for 30 s with 2000 ramp).
Softbake for 120 s at 115° C.
Expose AutoStepper using BLASERIDGE mask for 0.8 s
Develop in AZ327 for 280 s and then quick dip in DI
Descum as in step 6
14. Device Isolation Lithography/Lift-Off process
Sample solvent clean, same as in step 2
Sample under vacuum in Hexamethyldisilazane (HMDS) for 60 s
Spin nLOF 2020 using JD400030 recipe (4000 rpm for 30 s with 2000 ramp).
Softbake for 60 s at 110° C.
Expose in AutoStepper using BLISION mask for 0.2 s
Post-bake for 60 s at 110° C.
Develop in AZ917 for 120 s and then quick dip in DI
15. P-side Metallization (Oerlikon or FC1800 1 Evaporator)
Mount sample on at 45° angle stage (angle perpendicular to ridges)
Ti Gettering
100° A Ti @ 1° A/sec
1000° A Au @ 2° A/sec
Rotate sample 180° and repeat P-deposition
16. Lift-off Process Completion (nLOF removal)
Soak sample in PG remover at 90° C. for 30 min
Agitate using syringe
17. Lapping and Polishing (Allied Multiprep System)
Mount Sample onto polishing platen
(a) Heat platen to ˜135° C.
(b) Apply clear wax to platen
(c) Gently place sample face down into wax
(d) place platen on mounting press and gently apply pressure
9 μm paper down to ˜125 μm thick
(a) 150 RPM, CCW, full load
3 μm slurry on white pad to complete mirror shine (˜110 μm thick)
(a) 200 RPM, CW, full load
(b) Continue until all scratches removed from sample backside
1 μm slurry on black pad until final thickness of ˜100 μm
(a) 200 RPM, CW, full load
18. Wax removed in acetone
(a) Soak in acetone until sample is free of wax, typically 6-8 hours
19. Refresh etch, same as in step 4
20. N-side Metallization (Oerlikon or FC1800 1 Evaporator)
Ti Gettering
˜360° A Au0_{.88}Ge_{0.12} @ 2° A/sec. 1 pellet in thermal boat
˜60° A Ni @ 1° A/sec. Final thickness ratio of 1:6 Ni:Au_{0.88}Ge_{0.12}
1000° A Au @ 2° A/sec.
21. Metal Anneal (Allwin RTP)
7 s @ 410° C. 400 s ramp up and down
22. Cleave laser bars
Align sample on heat release tape
Scribe sample using diamond scribe while tape is held by vacuum, and everything monitored under the microscope
Scribed sample is now wrapped around cylindrical beaker and cleaved
The tape is now released from sample by placing on a 90° C. hot plate for 5 min.

In some aspects, the techniques described herein relate to a method including: etching through an active region of a semiconductor heterostructure to form a ridge structure having a ridge width; laterally etching the active region such that an active region width is less than the ridge width; depositing an oxide along the ridge structure; and depositing a metal layer.

In some aspects, the techniques described herein relate to a method, wherein laterally etching includes a selective etch configured to etch the active region without substantially etching the ridge structure.

In some aspects, the techniques described herein relate to a method, wherein the selective etch includes a wet etch.

In some aspects, the techniques described herein relate to a method, wherein depositing the oxide along the ridge structure includes depositing the oxide along sidewalls of the ridge structure without depositing the oxide along sidewalls of the active region.

In some aspects, the techniques described herein relate to a method, wherein depositing the oxide maintains an empty space around the active region.

In some aspects, the techniques described herein relate to a method, wherein etching through the active region includes a dry etch.

In some aspects, the techniques described herein relate to a method, wherein laterally etching the active region smoothens sidewalls of the active region from the dry etch.

In some aspects, the techniques described herein relate to a method, further including removing the oxide from a top surface of the ridge structure before depositing the metal layer.

In some aspects, the techniques described herein relate to a method, wherein depositing the metal layer includes depositing a first metal layer over the ridge structure and depositing a second metal layer along a substrate opposite the ridge structure.

In some aspects, the techniques described herein relate to a device including: a substrate; and a ridge structure on the substrate including: a lower cladding layer on the substrate having a first width; a quantum well over the lower cladding layer and having a second width less than the first width; and an upper cladding layer over the quantum well and having the first width.

In some aspects, the techniques described herein relate to a device, further including an oxide along sidewalls of the ridge structure.

In some aspects, the techniques described herein relate to a device, wherein a space between the quantum well and the oxide corresponding to a difference between the first and second widths is absent material.

In some aspects, the techniques described herein relate to a device, wherein the oxide includes a SiO₂ material.

In some aspects, the techniques described herein relate to a device, wherein the ridge structure further includes a cap layer at a top of the ridge structure.

In some aspects, the techniques described herein relate to a device, wherein the cap layer includes an InGaAs material.

In some aspects, the techniques described herein relate to a device, further including a first contact metal along the ridge structure and a second contact metal along the substrate.

In some aspects, the techniques described herein relate to a device, wherein the first contact metal and the second contact metal include different materials.

In some aspects, the techniques described herein relate to a device, wherein one or more of the substrate, the lower cladding layer, and the upper cladding layer includes an InP material.

In some aspects, the techniques described herein relate to a device, wherein the quantum well includes an AlInGaAs material.

In some aspects, the techniques described herein relate to an edge-emitter laser diode including: a first cladding layer and a second cladding layer; an optical guiding region structure sandwiched between the first and second cladding layers, and including a multi-quantum well sandwiched between graded-index separate-confinement-heterostructure (GRINSCH) layers, wherein a width of the optical guiding region structure is less than a width of the first and second cladding layers such that a gap surrounds the optical guiding region structure; and an oxide along the first and second cladding layers and outside of the gap.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A method comprising:
etching through an active region of a semiconductor heterostructure to form a ridge structure having a ridge width;
laterally etching the active region such that an active region width is less than the ridge width;
depositing an oxide along the ridge structure; and
depositing a metal layer.

2. The method of claim 1, wherein laterally etching comprises a selective etch configured to etch the active region without substantially etching the ridge structure.

3. The method of claim 2, wherein the selective etch comprises a wet etch.

4. The method of claim 1, wherein depositing the oxide along the ridge structure comprises depositing the oxide along sidewalls of the ridge structure without depositing the oxide along sidewalls of the active region.

5. The method of claim 4, wherein depositing the oxide maintains an empty space around the active region.

6. The method of claim 1, wherein etching through the active region comprises a dry etch.

7. The method of claim 6, wherein laterally etching the active region smoothens sidewalls of the active region from the dry etch.

8. The method of claim 1, further comprising removing the oxide from a top surface of the ridge structure before depositing the metal layer.

9. The method of claim 1, wherein depositing the metal layer comprises depositing a first metal layer over the ridge structure and depositing a second metal layer along a substrate opposite the ridge structure.

10. A device comprising:
a substrate; and
a ridge structure on the substrate comprising:
a lower cladding layer on the substrate having a first width;
a quantum well over the lower cladding layer and having a second width less than the first width; and
an upper cladding layer over the quantum well and having the first width.

11. The device of claim 10, further comprising an oxide along sidewalls of the ridge structure.

12. The device of claim 11, wherein a space between the quantum well and the oxide corresponding to a difference between the first and second widths is absent material.

13. The device of claim 11, wherein the oxide comprises a SiO₂ material.

14. The device of claim 10, wherein the ridge structure further comprises a cap layer at a top of the ridge structure.

15. The device of claim 14, wherein the cap layer comprises an InGaAs material.

16. The device of claim 10, further comprising a first contact metal along the ridge structure and a second contact metal along the substrate.

17. The device of claim 16, wherein the first contact metal and the second contact metal comprise different materials.

18. The device of claim 10, wherein one or more of the substrate, the lower cladding layer, and the upper cladding layer comprises an InP material.

19. The device of claim 10, wherein the quantum well comprises an AlInGaAs material.

20. An edge-emitter laser diode comprising:
a first cladding layer and a second cladding layer;
an optical guiding region structure sandwiched between the first and second cladding layers, and comprising a multi-quantum well sandwiched between graded-index separate-confinement-heterostructure (GRINSCH) layers, wherein a width of the optical guiding region structure is less than a width of the first and second cladding layers such that a gap surrounds the optical guiding region structure; and
an oxide along the first and second cladding layers and outside of the gap.
